(19) United States
(12) Patent Application Publication
(10) Pub. No.: US 2018/0161810 A1
(43) Pub. Date: Jun. 14, 2018

(54) OMNIPHOBIC SURFACE

(71) Applicant: AMF GmbH, Cologne (DE)

(72) Inventor: Karsten Reihs, Cologne (DE)

(21) Appl. No.: 15/526,241

(22) PCT Filed: Nov. 12, 2015
(86) PCT No.: PCT/EP2015/076492

§ 371 Date: Feb. 26, 2018

(30) Foreign Application Priority Data
Nov. 13, 2014 (DE) 10 2014 016 708.9

(51) Int. Cl. B05D 5/08; B05D 1/18; B05D 3/04

(52) U.S. Cl. CPC B05D 5/08; C23C 14/165; B05D 3/0466; B05D 1/185

(57) ABSTRACT

The invention relates to a structured surface with omniphobic properties, a method for producing said surface and the use thereof. When liquids are contacted with the structured surface the surface tension of the liquid is significantly increased. The omniphobic surface has a contact angle of >90° with respect to low-energy liquids such as squalene, as well as with respect to higher energy liquids such as water.

### CROSS REFERENCE TO RELATED APPLICATIONS

This is a US national phase application under 35 USC § 371 of international patent application no. PCT/EP2015/076492, filed Nov. 12, 2015, which itself claims priority to German application no. 10 2014 016 708.9, filed Nov. 13, 2014. Each of the applications referred to in this paragraph are herein incorporated by reference in their entireties herein.

### FIELD OF THE INVENTION

The invention relates to a structured surface having omniphobic properties. The surface has, in a high surface density, very small topographical structures with a lateral dimension of less than 10 Å. When a liquid comes into contact with the structured surface, the surface tension of the liquid increases far beyond the thermodynamic starting value which the liquid possesses without the small topographical structures. The omniphobic surface has an advancing angle >90° for liquids with any starting values of the surface tension.

The invention relates further to a method for producing the omniphobic surface and to uses thereof.

### BACKGROUND OF THE INVENTION

The production of an omniphobic surface—a surface with maximum dewetting for all liquids—is of great interest for a large number of industrial applications. The possible applications include, for example, coatings for self-cleaning glass surfaces in outdoor use, or use in microdosing systems for minimal dosing losses and high dosing accuracy. Because of the very great application potential there has been no lack of attempts to produce omniphobic surfaces on which all liquids form contact angles >90°. However, in view of the different applications, considerable limitations arise for the production of such surfaces in relation to their resistance, environmental compatibility and optical properties.

In order to change the wetting behaviour, in particular the contact angle, of a liquid in contact with a surface, two principles have been known for decades: 1. Wenzel method (Ind. Eng. Chem. 28, 988 (1936)) and 2. Cassie-Baxter method (Trans. Faraday Soc. 40, 546 (1944)). Both methods use a topographical structuring of the surface. Both principles are fundamentally suitable for producing surfaces for the pronounced dewetting of liquids and in many forms also occur in combination.

However, both the Wenzel and the Cassie mechanism have some systematic limitations. The Wenzel mechanism only has a more pronounced dewetting effect if the non-structured surface already forms a contact angle >90° with the liquid. Specifically for low-energy liquids with small contact angles (<90°), the structuring then leads to a reduction in the contact angle. Although the Cassie mechanism always leads to increased dewetting, the Cassie state is metastable and a transition to the Wenzel state can occur. A. Tuteja et al., PNAS 105, 18200 (2008) describe a method with which the metastable Cassie state can be stabilised by means of topographical structures with specially designed (re-entrant) geometry, which is important for the dewetting of low-energy liquids in particular.

A number of preparation methods for surfaces for pronounced dewetting of low-energy liquids (“superoleophobic” or “superomniphobic”) have recently been proposed. A common feature of all the preparation methods is a topographical surface structuring by the use of: 1. hierarchical structures on superposed length scales or 2. specially designed, lithographically produced structures with re-entrant geometries. In order to produce highly dewetting surfaces with low light scattering for practical applications, the topographical structures must be significantly smaller than the wavelength of light (<100 nm). As yet there is no surface which has extremely high contact angles for low-energy liquids and at the same time possesses a tolerable level of scattering losses for optical applications. Furthermore, the surfaces are usually provided with a hydrophobic auxiliary layer of fluoropolymers or siloxanes, which are soft and have little resistance.

In a publication by Mazumber et al., Nano Lett. 14, 4677 (2014), surfaces comprising hierarchical nanostructures modified with fluorosilanes are reported, which permit contact angles of up to 153° for hexadecane and 163° for oleic acid. Although comparatively good optical properties are reported, such a surface will have significant haze (1% haze). Furthermore, the use of an auxiliary layer of fluorosilanes is questionable for practical applications in view of stability and environmental compatibility.

In a publication by T. Liu and C. J. Kim, Science 346, 1096 (2014), a surface of mushroom-shaped structures with overhang geometry (double re-entrant) is reported, on which even low energy liquids with very low surface tensions of up to 10 mN/m form high contact angles >150°. The production of such surfaces, which does not require the surface material to be intrinsically dewettable, so that the use of a hydrophobic auxiliary layer becomes irrelevant, is also described in particular in WO 2015/048504 A2. However, such surfaces are based on a very expensive and uneconomical lithographic production process, and the large topographical structural dimensions (˜10 μm) are highly light scattering. In addition, the poor durability of such fragile structures greatly limits the practical usability of these surfaces.

### BRIEF SUMMARY OF THE INVENTION

Accordingly, the object is to provide surfaces which do not have the disadvantages of the described prior art.

In one aspect of the invention a structured surface having omniphobic properties is provided, characterized in that it has topographical structures having a lateral dimension of less than 20 angstroms and a vertical dimension of greater than 4 angstroms.

In some embodiments, the advancing angle for squalane is at least 90°. in further embodiments advancing angle for squalane is at least 120°. In still further embodiments the advancing angle for squalane is at least 150°.

In some embodiments, the advancing angle for water is at least 90°. In further embodiments, the advancing angle for water is at least 120°. In further embodiments, the advancing angle for water is at least 150°.

In some embodiments, the structured surface consists of carbon nanotubes.

In some embodiments the structured surface increases the surface tension of squalane on contact with the surface by a factor of at least 2.5.

In a related aspect of the invention, a method for producing a structured surface having omniphobic properties as summarized above is provided, characterized in that topographical structures having a lateral size of less than 20 angstroms and a vertical size of at least 4 angstroms are deposited.

In another related aspect, a material or building material having a structured surface as summarized above is provided.

In other related aspects, methods of using the structured surface for lining the walls of tubes or channels for the purpose of reducing the friction of liquid streams is provided. In other related methods of use, the structured surface is used as a transparent sheet or as a covering layer for transparent sheets, in particular glass or plastics sheets, in particular for solar cells, vehicles, aircraft or houses. In other related methods of use, the structured surface is used as non-transparent external elements of buildings, vehicles or aircraft. In still other methods of use the structured surface is used for transporting, dosing or storing small amounts of liquid.

### BRIEF DESCRIPTION OF THE DRAWINGS

The invention will be explained hereinbelow in examples with reference to drawings and tables.

FIG. 1: Schematic representation of a liquid surface. The liquid surface is roughened by thermally excited capillary waves of wavelength λ. The surface tension is the restoring force of the capillary waves; it “smoothes” the surface. The surface tension is inversely proportional to the amplitude of the capillary waves.

FIG. 2: Mole fraction of component F10H2 in a binary mixed monolayer of F8H2 and F10H2 in dependence on the concentration ratio R=c_{F10H2}/c_{F8H2} of the two components upon adsorption from ethanolic solution having a total concentration of 1 mM at 60° C. The open symbols represent the sum x_{F8H2}+x_{F10H2}=1 of the mole fractions determined independently of one another and thus represent a test of the consistency of the data. Ro denotes the concentration ratio in the solution at which an equimolar composition (x_{F8H2}=x_{F10H2}=0.5) of the adsorbed monolayer is obtained.

FIG. 3: Intensities n_{F8H2-F8H2}, n_{F8H2-F10H2} and n_{F10H2-F10H2} of binary cluster ions in dependence on the mole fraction x_{F10H2} in a binary mixed monolayer of the components F8H2 and F10H2. Binary cluster ions can be formed in the SIMS analysis of these monolayers only by two immediately adjacent thiolate chains in the monolayer. The solid lines show the intensities for a random distribution of the two chains in the binary monolayer and thus confirm the random arrangement of the components relative to one another for each monolayer composition.

FIG. 4: Schematic representation of the random arrangement of two components 1 and 2 in a binary molecularly mixed monolayer with equimolar composition of the components. The diameter of perfluorinated thiol chains on Au(111) is 5.6 Å, the distance to the nearest neighbour is 5.8 Å. The random arrangement of the two components results in a mean structural size of the one-component regions which is a multiple of the lateral dimension of the individual chains.

FIG. 5: Advancing angle θₐ of water for binary mixed monolayers of components F8H2 and F10H2 in dependence on the composition of the monolayer. The macroscopic surface tension γ predicts a profile which differs greatly from the measurements. The measured data can be described with a surface tension γ*=0.8γ according to equation (8).

FIG. 6: Selectively produced surface tension γ* relative to the macroscopic surface tension γ for water in contact with binary mixed monolayers with equimolar composition of components FyH2, whose length difference is Δh.

FIG. 7: Selectively produced surface tension γ* relative to the macroscopic surface tension γ for squalane in contact with binary mixed monolayers with equimolar composition of components FyH2, whose length difference is Δh.

FIG. 8: Scale-dependent surface tension γ(q) relative to the macroscopic surface tension γ at free liquid surfaces for water, squalane and octamethylcyclotetrasiloxane (OMCTS) in dependence on the wavelength q of the capillary waves. The data are taken from the publication Mora et al., X-Ray Synchrotron Study of Liquid-Vapor Interfaces at Short Length Scales: Effect of Long-Range Forces and Bending Energies, Phys. Rev. Lett. 90, 216101 (2003).

FIG. 9: Selectively produced surface tension γ* relative to the macroscopic surface tension γ for squalane in contact with binary mixed monolayers with equimolar composition of components Hy, whose length difference is Δh. For comparison, the data for components FyH2 from FIG. 6 are shown.

### DETAILED DESCRIPTION OF THE INVENTION

According to the invention, the stated object is achieved in that the surface tension of liquids when wetting surfaces having very small-scale structuring is increased.

Changes in the macroscopically effective surface tension γ are known in the case of highly curved free liquid surfaces. An important example is the surface tension of small liquid drops of the order of magnitude of a few nanometres. These curvature-dependent surface tensions are an important part of many processes in technology and nature. The expression “Tolman length”, which describes the curvature-dependent changes in surface tension, is the subject of many current scientific and technical works in this context.

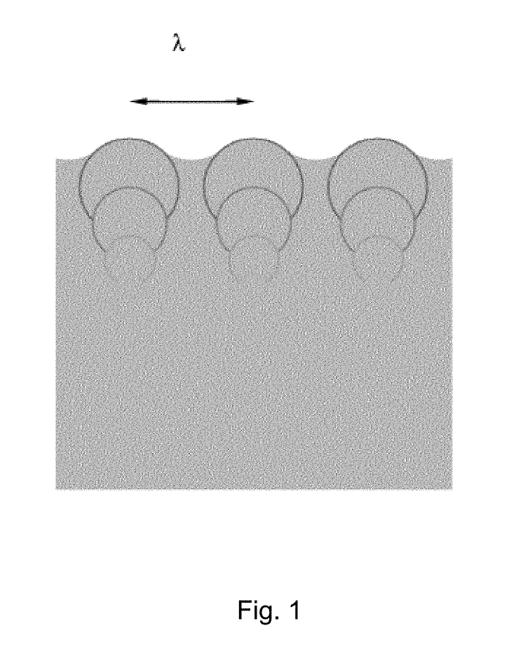

Free liquid surfaces, that is to say liquid-gas interfaces, at rest are not arbitrarily smooth; their structure is determined by the amplitudes of thermally generated capillary waves of wavelengths γ (see FIG. 1). The surface tension acts as the “restoring force” of the capillary waves and is inversely proportional to the amplitude of the capillary waves. The higher the “restoring force” for capillary waves of wavelength γ, the “smoother” the liquid on this length scale. The amplitudes of the capillary waves in the “roughened” surface can differ very characteristically at different wavelengths. Currently the most detailed description of small-scale corrections of the surface tension at free liquid-vapour interfaces is, experimentally, the data in the publication by Mora et al., Phys. Rev. Lett. 90, 216101 (2003) with the underlying theory of Mecke and Dietrich (Phys. Rev. E 59, 6766 (1999)).

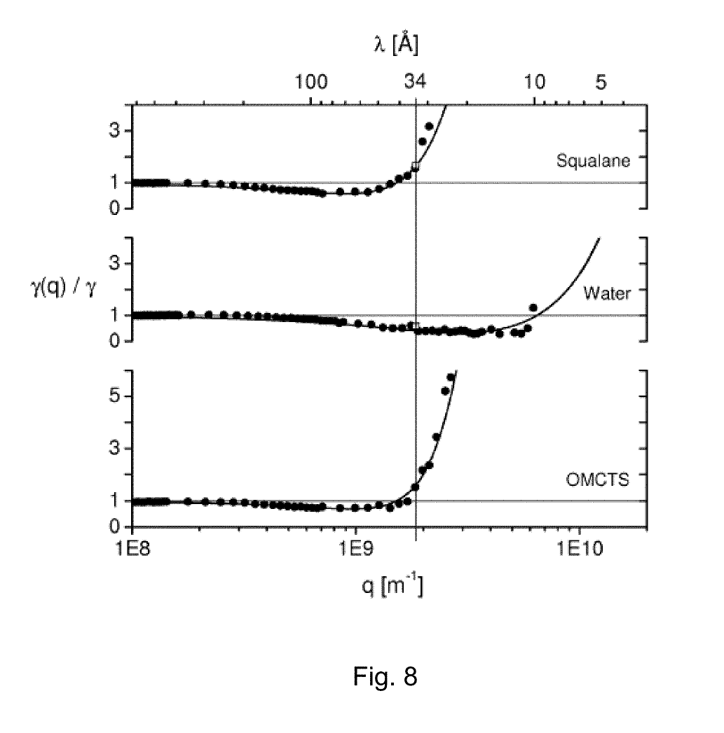

FIG. 8 shows, for three liquids, the profile of the ratios γ(q)/γ of the scale-dependent surface tension γ(q) and macroscopic surface tension γ in dependence on the wave vector q=2π/λ or the wavelength λ of the capillary waves at the free liquid surface. As the wavelength λ becomes smaller, there is first a reduction in the scale-dependent surface tension γ(q), before a sharp increase occurs at very small wavelengths. This very large increase in principle concerns any liquid. This is shown in FIG. 8 for octamethylcyclotetrasiloxane (OMCTS). The measured data show an increase in γ(q)/γ by a factor of 6. Measurement of the increases in γ(q)/γ for all liquids for small λ (˜10 Å) is limited by the experimental technique (grazing incidence X-ray diffraction).

None of these surface tensions γ(q) is effective in isolation for macroscopic wetting processes; only the totality of all the thermally excited capillary wave amplitudes results in the macroscopically effective surface tension γ of the free liquid-gas interface.

The basis of this invention is the wholly unexpected and surprising finding that liquids, upon contact with surfaces structured on a very small scale, allow the surface tensions γ(q) whose wavelengths λ correspond to the small-scale structure of the surface to become selectively macroscopically effective. The effective surface tension γ* selectively produced thereby represents the “new” macroscopically effective liquid-gas surface tension for wetting processes at that surface.

With the aid of this finding, a specific effective surface tension which determines the macroscopic wetting processes can be chosen by the structure of the surface.

A number of disadvantages of the prior art can thereby be avoided.

Firstly, with sufficiently small-scale structuring of the surface, all liquids can become maximally dewetting as a result of the pronounced increase in the surface tension which is in principle always present.

In addition, the surface can also be produced using materials which are not themselves hydrophobic or oleophobic. The use of fluorine surfactants which are not environmentally compatible and therefore not sustainable, as is necessary in almost all cases in the prior art, is not necessary and is even disadvantageous owing to the lower durability of these materials.

For the production of the surfaces according to the invention, very durable, non-hydrophobic or non-oleophobic materials such as carbon nanotubes can be used. The choice of materials is in principle a priori not limited.

As a result of the very small-scale structuring with dimensions smaller than 10 Å, the surfaces according to the invention can exhibit very low light scattering, so that the surfaces appear “clear” in transmission and are “glossy” in reflection. Optical applications, in which adhering liquid drops in particular are very disruptive, can therefore be served very advantageously with the surfaces according to the invention. However, since the structures for the wetting properties lie far outside the structure sizes that are effective for scattering (order of magnitude wavelength of light), it is also possible to produce surfaces with defined light scattering which in transmission are definitely “opaque” or in reflection are adjusted in a desired manner to be “matt”.

### EXAMPLES

General descriptions for the examples will first be explained hereinbelow.

a. Cleaning of the Silicon Substrates

Silicon wafers (Si(100), diameter 2 inches, thickness 275 μm, polished on one side) were each cleaned for 30 minutes with peroxomonosulfuric acid (“piranha solution”, concentrated H₂SO₄ and H₂O₂ (30%, v/v) in a ratio of 7:3 (v/v)), which was prepared immediately beforehand. Then the wafers were first rinsed with demineralised water, then cleaned for 15 minutes in demineralised water in an ultrasonic bath, rinsed with ethanol (denatured with 1% methyl ethyl ketone) and finally blown dry with Ar (purity 4.6).

b. Cleaning of the Glass Devices

For preparation of the coating solutions and for adsorption, glass vessels were used, which vessels were carefully cleaned as follows: The devices were first cleaned for 30 minutes with piranha solution (see above), then rinsed with flowing demineralised water, cleaned for 15 minutes in demineralised water in an ultrasonic bath and finally dried for at least 12 hours at 200° C. The devices were stored in aluminium foil until they were used within a few days.

c. Coating of the Silicon Substrates

The silicon wafers were coated by cathode sputtering (DC plasma, argon 6.0, Ar pressure 3×10⁻³ bar) first with a 20 nm thick layer of titanium (target 99.5%, 2 inch diameter, rate: 0.14 nm/s, FHR GmbH, Germany) and then, immediately thereafter, with a 200 nm thick layer of gold (target 99.99%, 2 inch diameter, rate: 1.12 nm/s, FHR GmbH, Germany). Immediately after being discharged from the vacuum of the coating installation (background pressure 2×10⁻⁷ mbar), the samples were placed in the adsorption solutions for coating.

d. Preparation of the Monolayers

The monolayers were adsorbed from binary solutions of the precursors at a total concentration of 1 mM in absolute ethanol (p.a.) which had previously been freed of dissolved air by introduction of Ar (purity 4.6) over a glass frit. Immediately after the silicon wafers had been discharged from the high vacuum of the coating installation after being coated with gold, the wafers were placed into the already prepared solutions and stored therein for at least 60 hours at 60° C. in closed vessels with ground-glass stoppers. After the adsorption, the samples were first placed in 1,1,1-trifluorotoluene (p.a.) for 15 minutes and then rinsed with dichloromethane (p.a.), toluene (p.a.) and absolute ethanol (p.a.) and dried in a stream of argon gas (purity 4.6). The samples were stored in dust-tight containers at ambient temperature for a period of several days until the analyses.

e. Analysis of the Monolayers by Static Secondary Ion Mass Spectrometry

The mole fractions of the components and the lateral distribution of the components in the binary mixed monolayers were determined by static secondary ion mass spectrometry (sSIMS) in a measuring system of the TOF.SIMS 300 type (ION-TOF GmbH, Munster, Germany) with a Bi primary ion beam of 25 keV energy at a primary ion dose density of 6×10¹² cm⁻² per spectrum on a rastered measuring surface of 200×200 μm². Positive and negative mass spectra were recorded, although the mole fractions and the lateral distributions of the components were determined solely by means of negative secondary ions. The spectra were calibrated with various signals of small mass (for example C, CH, CH₂, OH) as well as Au and Au₂. The mass resolution was typically Δm/m≈12,000 at about 100 Th.

In order to determine the mole fractions x₁ and x₂ of a binary mixed monolayer of components 1 and 2, the mass spectra of this mixed monolayer and the spectra of the monolayers of the individual components 1 and 2 are used. The determination is carried out with the aid of the signals of quasi-molecular ions. For fluorinated precursors of the type 1H,1H,2H,2H-perfluoro-n-alkylthiol (F—(CF₂)_{y}—(CH₂)₂—SH, abbreviated as FyH2), these are the secondary ions (Au F M-H)⁻ at a mass/charge ratio (m/z) of ky=295+50γ Th. For non-fluorinated precursors of the type n-alkylthiol (H—(CH₂)_{y}—SH, abbreviated as Hy), secondary ions (Au₂ M-H)⁻ at ky=427+14γ Th were used. The mole fractions x₁ and x₂ are determined according to:

$$x = \frac{{J}_{197}^{ky} ( {x}_{1} )}{{J}_{197}^{ky} ( {x}_{1} = 1 )} or x = \frac{{J}_{197}^{ky} ( {x}_{2} )}{{J}_{197}^{ky} ( {x}_{2} = 1 )} \qquad ( 1 )$$

The intensity ratio J is calculated from the ratio of the intensities of the molecular ions at the mass/charge ratio ky and the intensity of the gold ion Au⁻ at m/z=197 Th.

$${J}_{197}^{ky} = \frac{I ( m / z = ky )}{I ( m / z = 197 )} \qquad ( 2 )$$

The sum of the mole fractions x₁ and x₂ determined independently in this manner is x₁+x₂=1 within an error of typically ±2%, which serves to ensure the consistency of the mole fractions determined.

For both precursor types, the lateral distribution of the components of the binary monolayers was determined with the aid of the intensities of the secondary ions (Au (M-H)₂)⁻. In addition to the symmetrical dimer ions (similar M) at ky=355+100γ for FyH2 and at ky=263+28y for Hy, asymmetrical dimer ions (different-component M) are observed at ky=355+50y₁+50y₂ for FyH2 and ky=263+14 y₁+14 y₂ for Hy. The normalised intensity ratios of the symmetrical n₁₁, n₂₂ and asymmetrical n₁₂ dimer ions are determined as follows:

$${n}_{11} = \frac{{J}_{197}^{ky} ( {x}_{2} )}{{J}_{197}^{ky} ( {x}_{2} = 0 )} or \\ {n}_{12} = \frac{{J}_{197}^{ky} ( {x}_{2} )}{{J}_{197}^{ky} ( {x}_{2} = 0.5 )} or \\ {n}_{22} = \frac{{J}_{197}^{ky} ( {x}_{2} )}{{J}_{197}^{ky} ( {x}_{2} = 1 )} \qquad ( 3 )$$

For statistical reasons, for the theoretical ratio n₁₁:n₁₂:n₂₂

n₁₁:n₁₂:n₂₂=x₁²:2x₁x₂:x₁² (4)

and for the sum n₁₁+n₁₂+n₂₂=1. Within an error of typically a few percent, these theoretical ratios and sums are fulfilled. Since dimer ions are formed almost exclusively by direct neighbours in the monolayer (see Arezki et al., J. Phys. Chem. B 110, 6832 (2006)), equation (4) denotes a random distribution of the components in the monolayer.
f. Determination of the Contact Angle of Sessile Liquid Drops

The contact angles of sessile drops of liquids were determined using a contact angle goniometer of type ACA50 (DataPhysics GmbH, Germany) with a temperature-controlled sample container at 25° C. The measuring system had been calibrated with a lithographic profile of a sessile water drop with a contact angle of 120°.

All the contact angles were determined only dynamically. To that end, 20 μL of the liquid were metered onto the surface with a needle (100 μm outside diameter). While the needle remained in contact with the drop, the advancing behaviour upon enlargement of the triple line by addition of 5 μL of liquid, and the receding behaviour upon reduction of the triple line by removal of 15 μL of liquid, were recorded with a camera. Metering was always carried out at a rate of 0.15 μL/s. In order to determine the contact angle, the drop profile upon movement of the triple line was evaluated by first applying a base line to the drop profile. The advancing angle was determined as the mean value of about 50 individual values of the angle upon enlargement of the triple line during a period of about 5 seconds. The receding angle was determined as a single value at the time at which the triple line first became smaller upon removal of the liquid. All the contact angles were determined separately from the tangents at the triple line for the left and right side of the drop profile and were then averaged.

g. Determination of the Surface Tension

Determination of the surface tension γ_{LV} between the vapour phase (V) and the liquid phase (L) of the drop lying on the surface is given by the Young-Dupré equation with the contact angle θ_{Y}:

γ_{SV}−γ_{SL}=γ_{LV} cos θ_{Y} (5)

The interfacial tension γ_{SV} between the solid (S) and the vapour phase (V), and the interfacial tension γ_{SL} between the solid (S) and the liquid (L), cannot be determined directly. For γ_{SL} we use the known Girifalco-Good model, in which γ_{SL} can be expressed by the surface tension γ_{LV}, which can be determined by experiment:

γ_{SL}=γ_{SV}+γ_{LV}−2ϕ\sqrt{γ_{SV}γ_{LV}} (6)

The cosine of the contact angle θ of a liquid in contact with a rough surface is given by the cosine of the contact angle θ_{Y} of the “smooth” surface scaled with a factor r, which takes into account the enlarged surfaces of the rough surface:

cos θ=r cos θ_{Y} (7)

There is thus obtained a relationship with which the change in the surface tension γ_{LV} can be determined from the change in the contact angle θ on a rough surface:

$${( \frac{cos θ}{r} + 1 )}^{2} {γ}_{LV} = const . \qquad ( 8 )$$

In order to calculate the factor r, we model the surface by hexagonally arranged cylinders of van-der-Waals diameter 5.6 Å for FyH2 chains (Ulman et al., Langmuir 5, 1147 (1989)) and 4.5 Å for Hy chains (Wunderlich, Macromolecular Physics Vol. 1, chap. 2, Academic Press, New York, 1973, p. 97) with the known distances of nearest neighbours of 5.8 Å for FyH2 chains (Tamada et al., Langmuir 17, 1913 (2001), Alves et al., Langmuir 9, 3507 (1993), Liu et al., J. Phys. Chem. 101, 4301 (1994)) and 5.0 Å for Hy chains (Liu et al., Langmuir 10, 367 (1994), Strong et al., Langmuir 4, 547 (1988), Widrig et al., J. Am. Chem. Soc., 113, 2805 (1991)). The height differences of the chains are 1.25 Å per CF₂ group (Colorado et al., ACS Symposium Series 781, Washington, D C, 2001) and 1.18 Å per CH₂ group (Porter et al., J. Am. Chem. Soc. 109, 3559 (1987)).

### Example 1

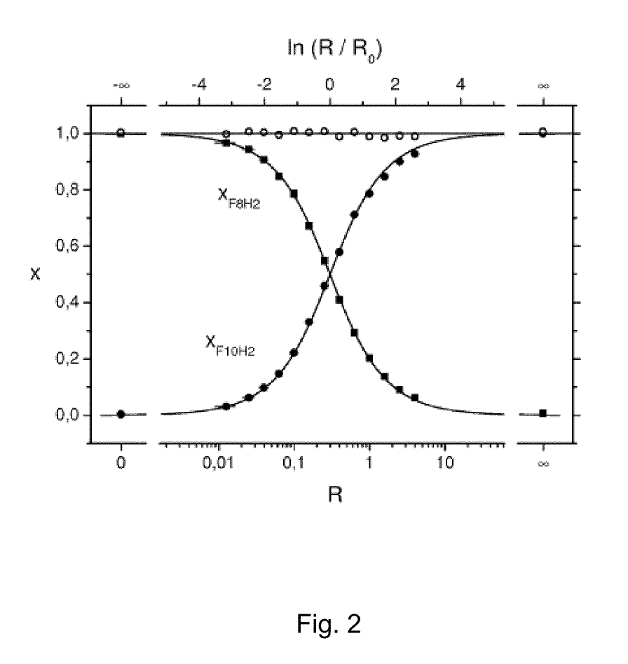

In accordance with the preceding description, a series of samples of binary mixed monolayers of components F8H2 and F10H2 was prepared by adsorption from ethanolic solutions of concentration ratios R=c_{F10H2}/c_{F8H2}. The abbreviation FyH2 denotes 1H,1H,2H,2H-perfluoro-n-alkylthiols F—(CF₂)_{y}—(CH₂)₂—SH. FIG. 2 shows the mole fractions in the monolayer which are established upon adsorption from solutions in dependence on the concentration ratio R. It will be seen that, under these conditions, for a concentration ratio in the adsorption solution of R₀=0.3, a binary monolayer with the mole fractions x_{F8H2}=x_{F10H2}=0.5 is formed (equimolar binary monolayer).

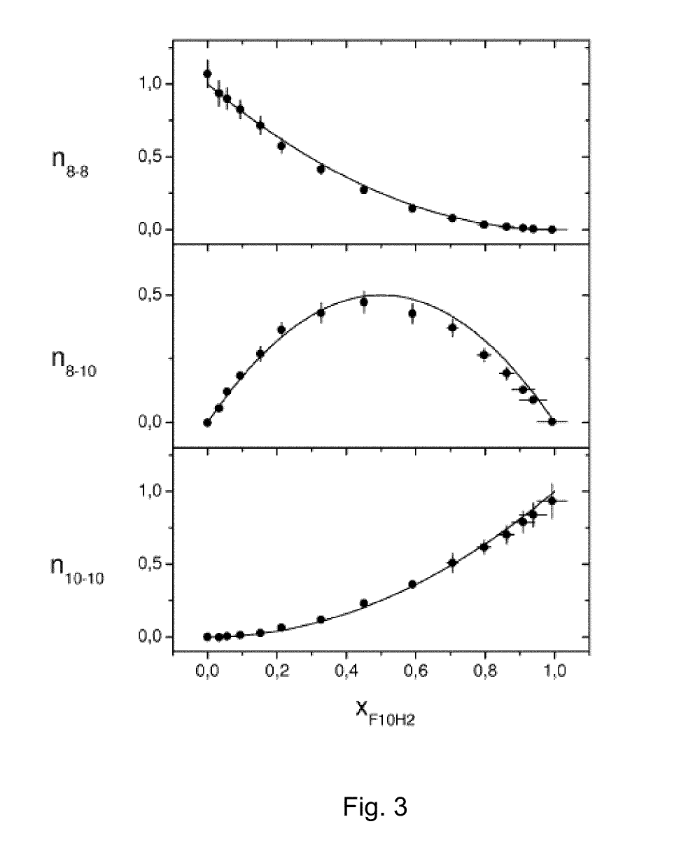

The lateral distribution of the adsorbed components F8H2 and F10H2 was analysed with the aid of the intensities of binary cluster ions by SIMS as described hereinbefore. FIG. 3 shows the intensities of cluster ions n_{F8H2-F8H2}, n_{F8H2-F10H2} and n_{F10H2-F10H2} in dependence on the mole fraction x_{F10H2}. Binary cluster ions can be formed by only two thiolates which are adsorbed immediately adjacent to one another in the monolayer. The solid lines in FIG. 3 show the intensities for a random distribution of the two components in the binary monolayer, which thus confirm the random arrangement of the components.

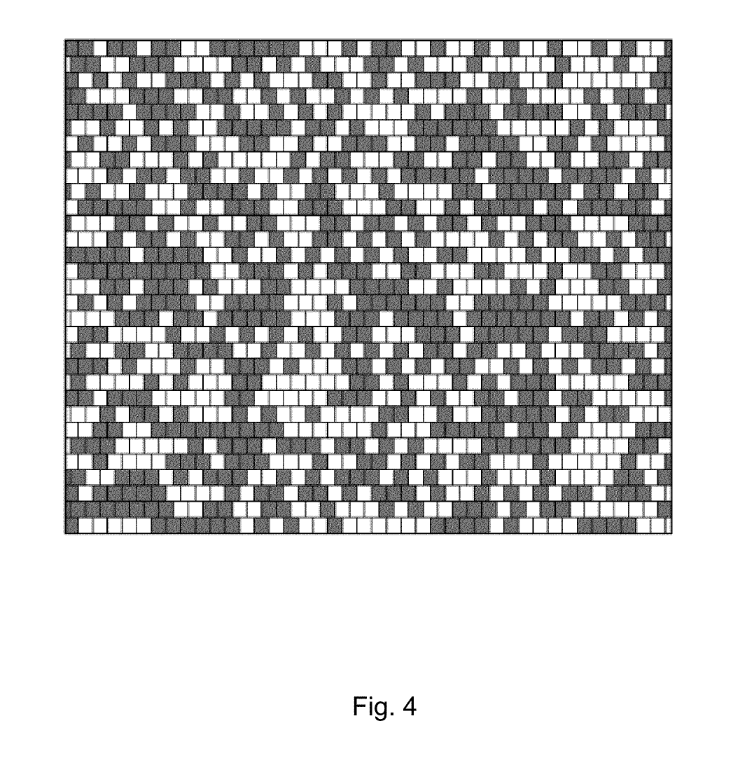

Such a random arrangement of the two components is shown schematically in FIG. 4 for a monolayer of equimolar composition. 1H,1H,2H,2H-Perfluoro-n-alkylthiols F—(CF₂)_{y}—(CH₂)₂—SH adsorb onto Au(111) surfaces in a hexagonal arrangement with a c(7×7) structure (Liu et al., J. Phys. Chem. 101, 4301 (1994), Tamada et al., Langmuir 17, 1913 (2001)). The distance between the immediately adjacent chains is 5.8 Å (see section g.), the van-der-Waals diameter of the chains is 5.6 Å (see section g.). As a result of the random arrangement of the chains, small one-component regions of very different shape and size form. The mean lateral structural size of these regions d is a multiple of the dimension of the individual chains and is thus d >5.8 Å.

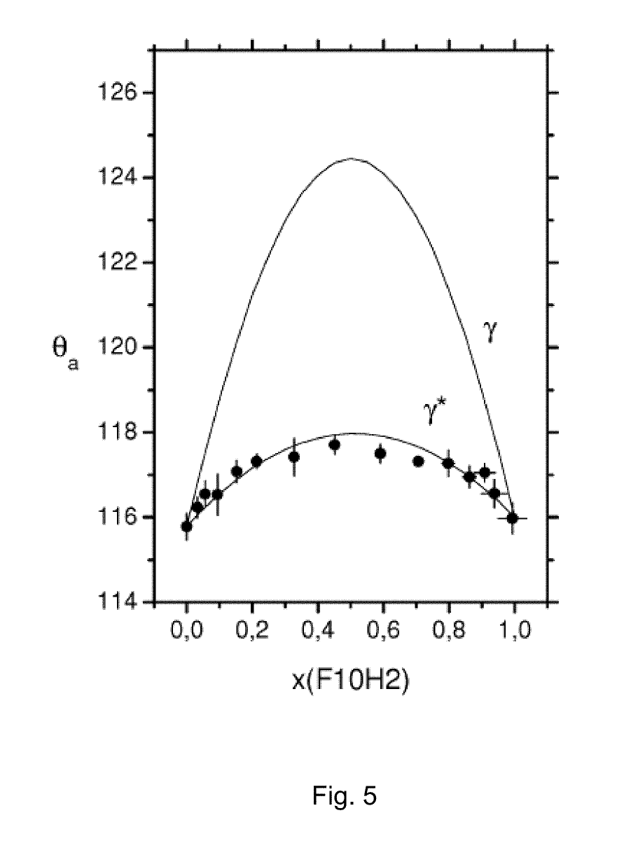

FIG. 5 shows the advancing angle for water drops with different mole fractions of the binary monolayers. If, as explained in section g., the contact angle profile is calculated with the aid of the Wenzel factor r and the macroscopic surface tension γ=72 mJ/m², a profile with substantially larger angles compared to the measured data is obtained. Thus, for example, with an equimolar composition of the monolayer, the calculated advancing angle is θₐ=124.5°, compared with the measurement of θₐ=118°. These differences are not caused by uncertainties relating to the structural parameters of the monolayers (van-der-Waals diameter, nearest neighbour distance and length differences of the chains), which are relatively accurately known. Completely implausible values for the parameters would have to be assumed therefor.

The measured advancing angles, by contrast, can be described with an actual effective surface tension γ* which is significantly smaller than the macroscopic surface tension γ. For γ*=0.8γ, advancing angles for water which correspond to the measured data in FIG. 4 are obtained.

Changes in the macroscopically effective surface tension γ are known in highly curved free liquid surfaces, for example in the case of small liquid drops of the order of magnitude of several nanometres. These phenomena are the basis of many technical processes and, under the expression “Tolman length”, for example, are the subject of current scientific works.

However, a change in the macroscopically effective surface tension of a liquid on contact with surface structures of the order of magnitude of a few nanometres is wholly surprising and completely unexpected.

### Example 2

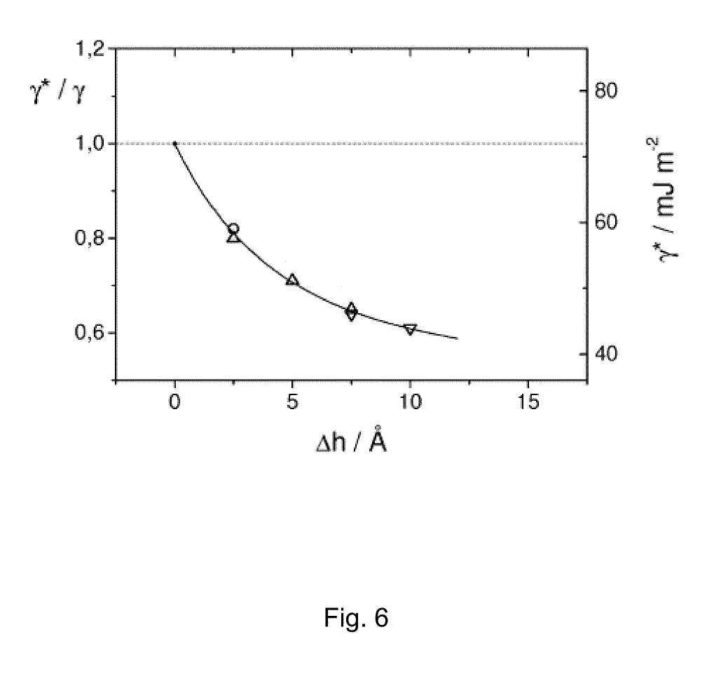

In accordance with the preceding description, series of samples for binary monolayers of systems Fy₁H2/Fy₂H2 with the combinations (y₁, y₂)=(10, 12), (8, 12), (8, 14), (6, 12), (6, 14) were prepared and analysed as shown in example 1. Together with the results for the system (F8H2, F10H2) from example 1, the selectively produced surface tensions relative to the macroscopic surface tension γ*/γ are plotted in FIG. 6 in dependence on the chain length difference Δh of the components of the binary monolayers.

With the same lateral structure, it is possible by increasing the vertical height differences Ah to bring about a further reduction in the surface tension γ*. This reduction of γ* diminishes significantly, however, at a height difference of about 10 Å.

### Example 3

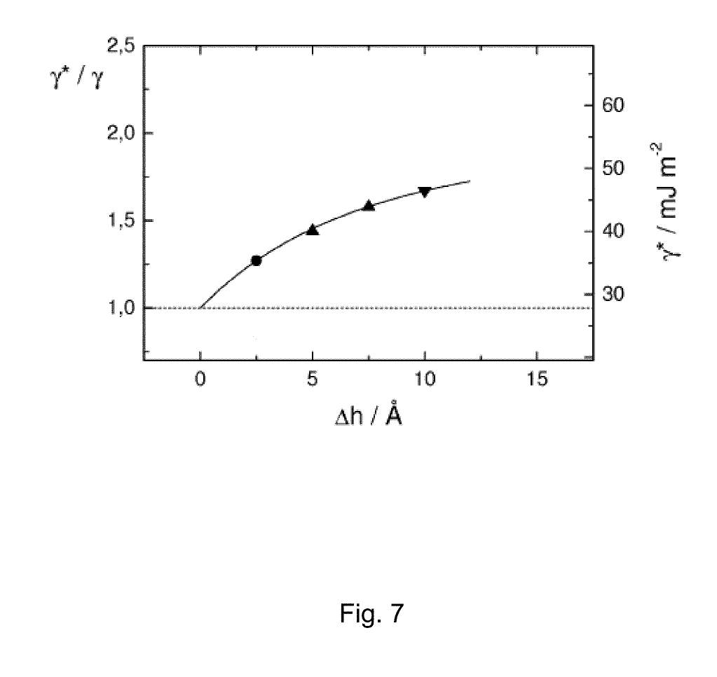

In accordance with the preceding description, series of samples for binary monolayers of systems Fy₁H2/Fy₂H2 with the combinations (y₁, y₂)=(10, 12), (8, 12), (8, 14), (6, 14) were prepared and analysed as shown in example 2. FIG. 7 shows the surface tension ratios γ*/γ calculated from the advancing angles of squalane (2,6,10,15,19,23-hexamethyltetracosane) as for example 2.

For squalane, in contrast to water in example 2 (FIG. 6), a significant increase in the selectively produced surface tension relative to the macroscopic surface tension γ*/γ is seen.

With the same lateral structure, a further, in contrast to water, but further increase in the surface tension γ* occurs as a result of an increase in the vertical height differences Ah. This increase in γ* again diminishes significantly at a height difference of about 10 Å.

### Example 4

FIG. 8 shows small-scale corrections of the surface tension at free liquid-vapour interfaces from the publication by Mora et al., Phys. Rev. Lett. 90, 216101 (2003). These data and the underlying theory of Mecke and Dietreich (Phys. Rev. E 59, 6766 (1999)) are at present the most detailed description of the small-scale structure of free liquid surfaces, that is to say of the liquid-vapour interfaces.

The ratios γ(q)/γ of the scale-dependent surface tension γ(q) and macroscopic surface tension γ in dependence on the wave vector q=2π/λ or the wavelength λ of the capillary waves at the free liquid surface are shown. The surface tension γ(q) is inversely proportional to the amplitude of the capillary waves, that is to say it is the “restoring force” of the capillary waves and “smoothes” the surface roughened by the capillary waves to a certain extent.

In FIG. 8, a significant fall in the surface tension γ(q) (fall in the capillary wave amplitude) at and above 10⁹ m⁻¹ (λ=2π/q=63 Å) is seen, before the surface tension γ(q) increases sharply (fall in the capillary wave amplitude) at q=7×10⁹ m⁻¹ (λ=9 Å) and the water thus becomes significantly “smoother” for λ<9 Å. None of these surface tensions γ(q) is effective in isolation; only the totality of all the thermally excited capillary waves results in the macroscopically effective surface tension γ.

If the surface tensions γ*/γ determined by experiment from FIGS. 6 and 7 are compared, for example at a height difference of 5 Å of the binary monolayers, then the values for water γ*/γ=0.71 and squalane γ*/γ=1.45 correspond in approximately the same wave vector 1.9×10⁹ m⁻¹. It thus appears that, upon contact of the liquids with the very small-scale structured surface, only certain capillary waves would selectively contribute to the macroscopically effective surface tension. These actually effective lateral structures correspond in this example to capillary wavelengths of 34 Å.

### Example 5

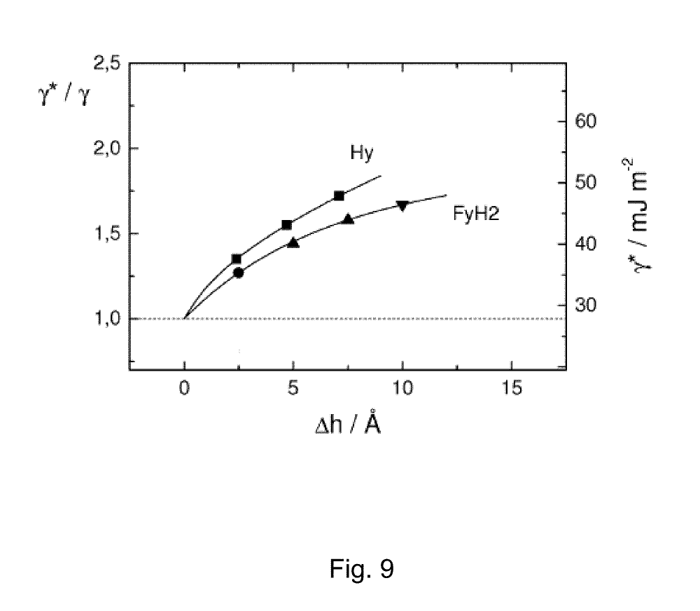

In accordance with the preceding description, series of samples for binary monolayers of components Hy₁/Hy₂ non-fluorinated n-alkylthiols (Hy, SH—CH₂)_{y}—H) with the combinations (y₁, y₂)=(18, 20), (16, 20), (12, 18) were prepared and analysed as shown in example 3. FIG. 9 shows the surface tension ratios γ*/γ calculated from the advancing angles of squalane (2,6,10,15,19,23-hexamethyltetracosane) as for examples 2 and 3.

A greater increase in the surface tension γ* is seen for the binary monolayers of the Hy systems as compared with the FyH2 systems. Considering the smaller van-der-Waals diameter of the Hy chains compared with the FyH2 chains (4.5 Å and 5.6 Å) and the smaller nearest neighbour distance (5.0 Å and 5.8 Å), smaller capillary wavelengths are selected with the smaller structures of the Hy systems, so that an increase in the selectively produced surface tension occurs for squalane (see FIG. 8).

### Example 6

In accordance with the preceding description, a binary monolayer of components F8H2/F12H2 was prepared and analysed as in example 3. The height difference Δh for this system is Δh=5 Å. The surface tension ratio γ*/γ=1.76 was calculated from the advancing angles for octamethylcyclotetrasiloxane (OMCTS). The significant increase in γ* again corresponds qualitatively to the structure of the free OMCTS surface according to FIG. 7 and according to the explanations relating to example 4.

### Example 7

In accordance with the preceding description, a binary monolayer of components F8H2/F12H2 was prepared and analysed as in example 6. The surface tension ratios γ*/γ calculated from the advancing angles for different liquids are shown in table 1.

For most liquids 1 to 12, an increase in γ*/γ by from 40% to 80% is seen for the F8H2/F12H2 structure used. Hydrogen-bridge-forming liquids such as water and ethylene glycol have significantly smaller γ*/γ. In these liquids, the increases in the surface tensions only occur at large wave vectors in the γ(q)/γ profiles, as compared with the other liquids. The present relatively large lateral structural dimensions of the F8H2/F12H2 structures can obviously not yet lead to the selective formation of very small capillary wavelengths with large surface tensions.

### Example 8

The preceding examples show that the lateral dimensions of the structures shown are still too small for the production of very large surface tensions γ*. Even the very small van-der-Waals diameters of the alkyl or fluorinated alkyl chains with dimensions of 4.5 Å and 5.6 Å and nearest neighbour distances of 5.0 Å and 5.8 Å still lead in monolayers with randomly arranged molecules to actually effective structural lengths which are a multiple of those dimensions.

By contrast, materials and methods are known to a person skilled in the art with which lateral structures can be produced in which the dimensions of the components are smaller than those of the adsorbed alkyl or fluorinated alkyl chains. Thus, for example, a number of publications are known in which PECVD methods for the deposition of vertically oriented carbon nanotubes (VA-CNT) are described (Meyyappan et al., Carbon nanotube growth by PECVD: a review, Plasma Sources Sci. Technol. 12, 205 (2003) and Meyyappan, A review of plasma enhanced chemical vapour deposition of carbon nanotubes, J. Phys. D: Appl. Phys. 42, 213001 (2009)).

The smallest carbon nanotube of armchair structure (2,2) has a diameter of 3 Å (Zhao et al., Phys. Rev. Lett. 92, 125502 (2004)), which has hitherto been produced, however, only as the innermost structure in a multiwall tube. The smallest free-standing tube currently deposited has a single-wall structure (5,1) or (4,2) with a diameter of 4.3 Å (Hayashi et al., Nano Lett. 3, 887 (2003)).

Such carbon nanotubes are suitable for constructing very small topographical structures in a particular manner. In contrast to the adsorbed alkyl or fluorinated alkyl chains, whose diameters have similar dimensions, in the case of vertically oriented carbon nanotubes in a dense arrangement, the length distribution of the tubes upon deposition does not lead to greatly increased structural dimensions as a result of larger regions of uniform vertical structural lengths. The diameters of the carbon nanotubes of about 4 Å therefore result in surfaces with lateral structural dimensions of the same order of magnitude.

It can be seen from FIG. 8 that, with structural lengths of 3-4 Å, a greatly increased surface tension γ* can be achieved even in the case of associated liquids such as water.

TABLE 1
Table 1: Comparison of the selectively produced surface tension γ*
relative to the macroscopic surface tension γ for different liquids
in contact with a surface of a binary mixed monolayer with equimolar
composition of components F8H2 and F12H2.

| | | Ratio of selectively produced γ* surface |
|---|---|---|
| | | tension and macroscopic surface tension γ |
| No. | Liquid | γ*/γ |
| 1 | OMCTS | 1.76 |
| 2 | n-Pentane | 1.70 |
| 3 | n-Hexane | 1.67 |
| 4 | Ethanol | 1.64 |
| 5 | n-Heptane | 1.63 |
| 6 | n-Octane | 1.61 |
| 7 | n-Nonane | 1.58 |
| 8 | n-Decane | 1.55 |
| 9 | Acetone | 1.53 |
| 10 | Carbon tetrachloride | 1.45 |
| 11 | Squalane | 1.44 |
| 12 | Toluene | 1.41 |
| 13 | Ethylene glycol | 1.07 |
| 14 | Water | 0.71 |

1. A structured surface having omniphobic properties, characterized in that it has topographical structures having a lateral dimension of less than 20 angstroms and a vertical dimension of greater than 4 angstroms.

2. The structured surface according to claim 1, characterized in that the advancing angle for squalane is at least 90°.

3. The structured surface according to claim 1, characterized in that the advancing angle for squalane is at least 120°.

4. A structured surface according to claim 1, characterized in that the advancing angle for squalane is at least 150°.

5. The structured surface according to claim 1, characterized in that the advancing angle for water is at least 90°.

6. A structured surface according to claim 1, characterized in that the advancing angle for water is at least 120°.

7. The structured surface according to claim 1, characterized in that the advancing angle for water is at least 150°.

8. The structured surface according to claim 1, characterized in that it consists of carbon nanotubes.

9. The structured surface according to claim 1, characterized in that it increases the surface tension of squalane on contact with the surface by a factor of at least 2.5.

10. A method for producing a structured surface having omniphobic properties according to claim 1, characterized in that topographical structures having a lateral size of less than 20 angstroms and a vertical size of at least 4 angstroms are deposited.

11. A material or building material having a structured surface according to claim 1.

12. A method of using the structured surface according to claim 1 for lining the walls of tubes or channels for the purpose of reducing the friction of liquid streams.

13. A method of using the structured surface according to claim 1 as a transparent sheet or as a covering layer for transparent sheets, in particular glass or plastics sheets, in particular for solar cells, vehicles, aircraft or houses.

14. A method of using the structured surface according to claim 1 as non-transparent external elements of buildings, vehicles or aircraft.

15. A method of using the structured surface according to claim 1 for transporting, dosing or storing small amounts of liquid.
